(19) United States
(12) Patent Application Publication
(10) Pub. No.: US 2015/0162225 A1
(43) Pub. Date: Jun. 11, 2015

(54) APPARATUS AND METHOD FOR WET-CHEMICAL PROCESSING OF FLAT, THIN SUBSTRATES IN A CONTINUOUS METHOD

(71) Applicant: acp-Advanced Clean Production GmbH, Esslingen (DE)

(72) Inventor: Horst Kunze-Concewitz, Wiemsheim (DE)

(21) Appl. No.: 14/570,030

(22) Filed: Dec. 15, 2014

Related U.S. Application Data
(63) Continuation of application No. 12/126,870, filed on May 24, 2008, now abandoned.
Application No. 12/126,870 is a continuation of application No. PCT/EP2006/011166, filed on Nov. 22, 2006.

(30) Foreign Application Priority Data
Nov. 26, 2005 (DE) 10 2005 057 109.3

(51) Int. Cl. H01L 21/67; B05D 1/28; H01L 21/02; B05C 1/00

(52) U.S. Cl. CPC H01L 21/67075; B05C 1/00; B05D 1/28; H01L 21/67028; H01L 21/02104

(57) ABSTRACT

The invention relates to a method and apparatus for wet-chemical processes (cleaning, etching, stripping, coating, dehydration) in a continuous method for flat, thin and fracture-sensitive substrates, the substrate transport and the wet process being effected by media-absorbing rollers.

### CROSS-REFERENCE TO RELATED APPLICATIONS

This application is a continuation of U.S. patent application Ser. No. 12/126,870 filed on May 24, 2008, which is a continuation of International Application No. PCT/EP2006/011166 filed on Nov. 22, 2006, which claims the benefit of DE 10 2005 057 109.3, filed Nov. 26, 2005. The entire disclosures of the above applications are incorporated herein by reference.

### FIELD

The invention relates to a method and an apparatus for the wet-chemical processing of flat, thin and fracture-sensitive substrates for microelectronic, micromechanical, and optical applications.

### BACKGROUND

The statements in this section merely provide background information related to the present disclosure and may not constitute prior art.

The wet process technique for the production of microelectronic components is presently carried out primarily in bath processes, wherein the substrates, which are accommodated in magazines, are immersed in process baths. The process is carried out discontinuously in batches of 1 to 50 substrates. The use of continuous (inline) wet process systems, for example for the production of solar cells, is on the rise, wherein the substrates located on rollers or belts are continuously conveyed into process baths or are sprayed in spray modules with media, such as process chemicals or water, and then dried with warm air or nitrogen, which may optionally be enriched with isopropanol. The presently available wet-chemical processes are limited to immersion processes and spraying processes, which were developed and optimized substantially for standard substrates in the semi-conductor industry. In modern microelectronics and thin-film technology, in the future increasingly thinner substrates will be used, for example with substrate thicknesses of less than 100 μm. These practically film-like, very fracture-sensitive substrates cannot be processed in magazines and immersion basins because on the one hand the requirements with respect to transportation stability, and on the other also the productivity criteria, are not met. Some process requirements, such as one-sided processing, are also not possible. While existing inline process systems for the simultaneous processing of a large number of such substrates in a continuous method meet the throughput criteria, they are associated with unacceptably high breakage rates and cannot be employed for all necessary process types.

### SUMMARY

The method described hereinafter, and the apparatus that is described, meet all the requirements for an inline process device for thin, fracture-sensitive substrates, both with respect to the transport (handling) within the process path and also with respect to the expanded processes for all required applications through the use of microporous, compressible rollers. By using such rollers, forces perpendicular to the transport direction are avoided, and at the same time the rollers allow uniform coverage of the substrates with the process media, either on both sides or only on the front or back of the substrate. As a result, during processing not only chemical, but also physical methods with direct cleaning contact are effective through the controlled interaction with the process media. In addition, a rinsing and drying step can be integrated in the same method.

In the present method, the substrates to be processed are guided in a continuous method via rotating, media-compatible sponge rollers that are installed on one side or both sides. Absolutely uniform movement is achieved by coupling the drives on at least one side. The media (liquid or gaseous) required for the desired process are applied directly or indirectly during the pass and are removed again in rinsing and drying steps. Depending on the embodiment, processing can be performed on one side or both sides of the substrates, and a plurality of process steps (using the same or different media) can be combined in one process line by stringing process modules together. This line can have one or more lanes. The method can end both with wet or dry substrates. The method described hereinafter, and the apparatus that is described, meet all the requirements for an inline process device for thin, fracture-sensitive substrates, both with respect to the transport (handling) within the process path and also with respect to the expanded processes for all required applications through the use of microporous, compressible rollers. By using such rollers, forces perpendicular to the transport direction are avoided, and at the same time the rollers allow uniform coverage of the substrates with the process media, either on both sides or only on the front or back of the substrate. As a result, during processing not only chemical, but also physical methods with direct cleaning contact are effective through the controlled interaction with the process media. In addition, a rinsing and drying step can be integrated in the same method.

In the present method, the substrates to be processed are guided in a continuous method via rotating, media-compatible sponge rollers that are installed on one side or both sides. Absolutely uniform movement is achieved by coupling the drives on at least one side. The media (liquid or gaseous) required for the desired process are applied directly or indirectly during the pass and are removed again in rinsing and drying steps. Depending on the embodiment, processing can be performed on one side or both sides of the substrates, and a plurality of process steps (using the same or different media) can be combined in one process line by stringing process modules together. This line can have one or more lanes. The method can end both with wet or dry substrates.

Further areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way.

In order that the invention may be well understood, there will now be described an embodiment thereof, given by way of example, reference being made to the accompanying drawing, in which:

FIG. 1 is a side view of a process module into which substrates to be processed are fed in accordance with the principles of the present disclosure;

FIG. 2 is a side view of rollers of the process module in accordance with the principles of the present disclosure;

FIG. 3 is side view illustrating an alternative method, wherein process media can additionally be guided by spray nozzles in accordance with the principles of the present disclosure;

FIG. 4 is a side view illustrating media being fed to a roller through a roller core in accordance with the principles of the present disclosure;

FIG. 5 is a side view illustrating an alternate process, wherein rollers rotate in opposite directions, for example during cleaning processes, in accordance with the principles of the present disclosure;

FIG. 6 is a side view illustrating rollers and the vertical distance of the rollers in relation to the substrate and the horizontal distance of the rollers to one another as well as the roller quantity being configured in accordance with the principles of the present disclosure;

FIG. 7 is a side view illustrating another form of rollers having different roller diameters in accordance with the principles of the present disclosure;

FIG. 8 is a side view illustrating additional wiping and/or rolling in accordance with an alternate form of the present disclosure;

FIG. 9 is a side view illustrating an alternate form of introducing a gas steam mixture into the liquid on the substrate surface in accordance with the principles of the present disclosure;

FIG. 10 is a side view illustrating one-sided surface treatment of a substrate in accordance with the principles of the present disclosure;

FIG. 11 is a side view illustrating an alternate form of one-sided surface treatment in which rollers are immersed in a process medium in accordance with the principles of the present disclosure;

FIG. 12 is a side view of an alternate form of surface treatment according to FIG. 11 in which pressure rollers are employed in accordance with the principles of the present disclosure; and

FIG. 13 is a side view illustrating pressure rollers in accordance with the principles of the present disclosure.

### DETAILED DESCRIPTION

The following description is merely exemplary in nature and is not intended to limit the present disclosure, application, or uses.

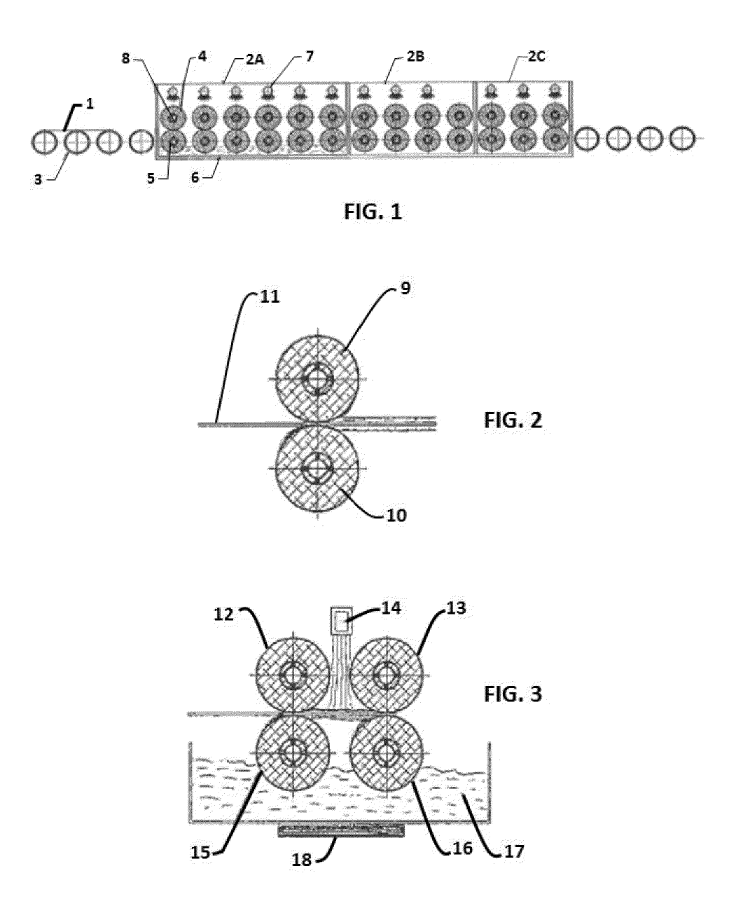

The substrates 1 (FIG. 1) to be processed are fed horizontally to a process module 2A. Feeding is carried out in that the substrate is transported on rollers 3 or on bands or belts, or by an alternative handling system (such as robots), to the rollers 4 and 5 of the process modules 2A.

As soon as the substrate is picked up by the porous, compressible rollers 4 and 5, the substrate is conveyed further by identical, subsequent rollers of the process module 2A. The rollers are characterized in that they absorb the process medium used in the process module 2A, wherein the medium is fed from an immersion bath 6 or spraying device 7, or directly through the core of the rollers 8, and in that they transmit the process medium to the substrate surface due to the contact of the rollers 9 and 10 (FIG. 2) with the surface of the substrate 11. The rolling motion of the roller fed with the process medium on the substrate surface at the same time effects a friction effect, which supports the process and intensifies processing during cleaning, etching, stripping, and rinsing.

In an alternative method, which can also be combined with that described above, the distance of the rollers 12 and 13 (FIG. 3) can be configured such that between the rollers 12 and 13 process media can additionally be guided by spray nozzles 14. Furthermore, the spray nozzles can be configured as ultrasonic or megasonic nozzles.

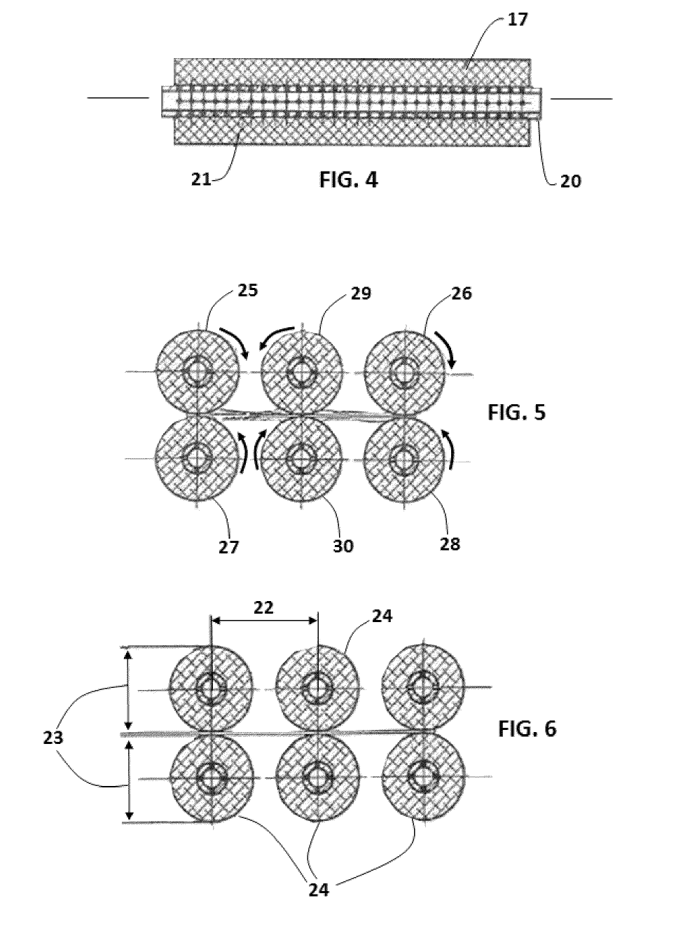

Coverage of the lower rollers 15 and 16 can optionally be achieved by the direct absorption of the process medium from the tub 17, or according to the above-described embodiment of the upper rollers via spray nozzles, and can additionally be supported by ultrasonic or megasonic excitation (18) of the process medium. The media can also be fed to the roller 19 (FIG. 4) through the roller core 20 in that the roller core is provided with bores 21 for discharging the media. Due to the microporous structure of the roller, the process medium reaches the roller body and/or roller surface and, in the apparatus that is described, the surfaces of the substrate to be processed.

Depending on the substrate type and the desired process, both the vertical distance 23 of the rollers in relation to the substrate (FIG. 6) and the horizontal distance 22 of the rollers to one another as well as the roller quantity 24 can be configured in accordance with the process requirements and substrate type. Likewise, the pressure of the rollers on the substrate can be brought about in accordance with the desired process and substrate type by means of fine adjustment, gravity (pressure of the upper rollers on the lower rollers), or by actuators (pneumatic, electric, or hydraulic). The rollers are rotated by electric drives in that the roller rotation and thus the substrate transport is continuously variable.

Alternatively, a process wherein the rollers rotate in opposite directions, for example during cleaning processes, is possible (FIG. 5) in that the roller contact pressure of the rollers 25, 26, 27 and 28 performing the substrate transport is accordingly higher in relation to the substrate than the roller contact pressure of the rollers 29 and 30, and in that the rollers 29 and 30 rotate opposite to the direction of rotation of the rollers 25, 26, 27 and 28 and/or opposite to the transport direction of the substrate, thus creating an additional cleaning effect.

Likewise, rollers having different roller diameters (FIGS. 7) 31, 32, 33 and 34 can be used for the transport and processing, if they are adapted in their combination to the process (see FIG. 7). In addition, the rotational speed of each roller can be individually controlled and, in combination with the roller pressure and roller direction of rotation, can be associated with every roller in order to achieve appropriate process control during the individual processes.

For different, consecutive processes, such as etching, rinsing, drying, the process modules can be set up successively in a line 2A, 2B, 2C (see FIG. 1) and be separated from one another with respect to the different process media by separating walls, comprising a slot for continuous substrate transport. Separation of the process modules from one another can also be achieved solely by the rollers and appropriate process media supply in that the last rollers within the process modules are supplied a reduced media volume.

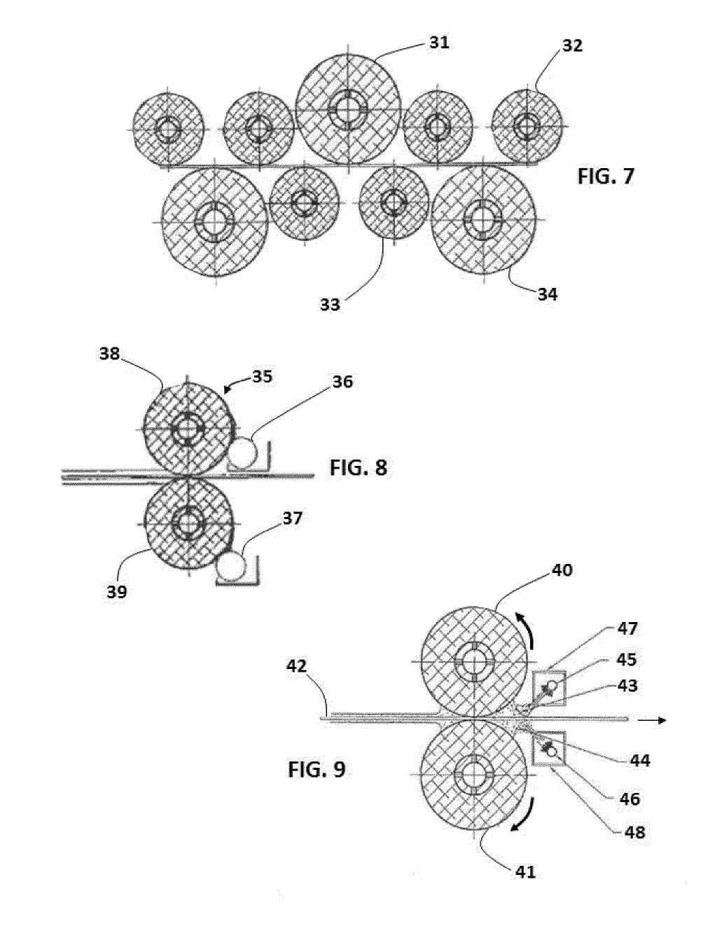

Drying of the substrate surface, for example after spraying processes, is likewise performed substantially by the microporous rollers. However, these rollers are not supplied a process medium. Due to the rolling motion of the dry roller across the substrate surface, the roller absorbs liquid from the surface (see FIG. 8). The absorbed liquid is continuously removed through additional wiping and/or rolling 36 and 37 (FIG. 8) of the rollers 39 and 39 used for the drying process, thus preparing the roller for further absorption of liquid in a process run. Likewise, the liquid absorbed by the roller can be removed from the substrate surface in that the absorbed liquid is suctioned out of the roller through the perforated roller core 20 (FIG. 4) by a vacuum.

In a second embodiment, surface drying after absorption of the liquid following the rolling motion of the rollers on the substrate surface can occur in that following the last roller the substrate surface is inflated with gases, which can additionally be heated, such as heated nitrogen or hot air, and by heating the substrate, for example by means of infrared radiation or heating rods, or in a combination of the described methods.

In a further, alternative embodiment, residue-free surface drying of the substrates can be carried out by introducing a gas-steam mixture into the liquid on the substrate surface, wherein the steam can be mixed with the liquid and mixing results in reduced surface tension of the liquid on the interface between the substrate and roller surfaces compared to the liquid without admixed steam. This method, known as the Marangoni effect or surface tension gradient drying, can be applied to the present invention, as is shown in FIG. 9. Due to the rolling motion of the rollers 40 and/or 41, the liquid previously absorbed from the wet substrate surface during rolling of the rollers, or the liquid additionally fed to the rollers according to the possibilities described above, produces a meniscus between the roller and substrate surface. From the nozzles 45 and/or 46, the gas-steam mixture is conducted in the direction of the meniscus through flow-conducting outlets 47 and/or 48. If the steam penetrates the liquid meniscus, mixing and therefore a reduction in surface tension in relation to the liquid outside of the meniscus are brought about. This results in a force (Marangoni force) in the direction of the liquid region having higher surface tension outside of the meniscus, which causes the substrate to dry. This drying process is substantially free of particles and residue.

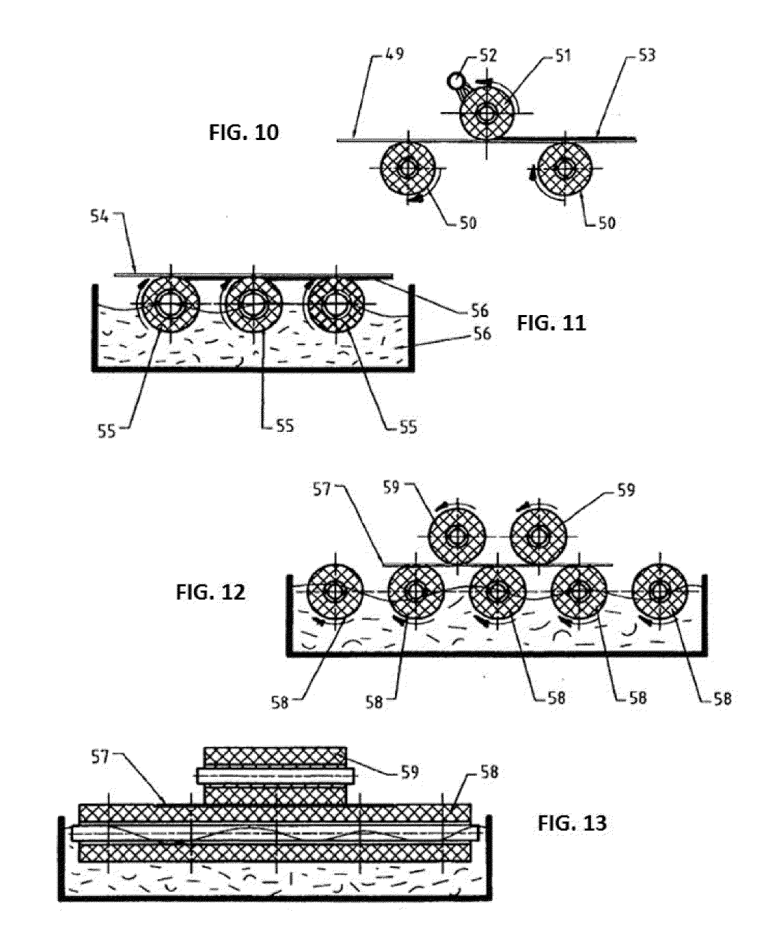

The one-sided surface treatment of a flat substrate can occur in that the substrate 49 (FIG. 10) is fed on conveying rollers 50 to a process roller 51, which is supplied with a process medium 52 and transfers the process medium 53 onto the substrate surface during the rolling motion across the substrate. The appropriate arrangement of the conveying rollers 50 prevents them from coming in contact with the process roller 51.

A further possibility of one-sided surface treatment can occur in that the substrate 54 (FIG. 11) is transported with the surface to be processed by the rollers 55, which are immersed in a process medium and during rotation of the rollers during the substrate transport transmit this medium 56 to the substrate bottom. If this substrate 57 (FIG. 12) is additionally pressed against the soft rollers 58 by pressure rollers 59 (FIG. 13), also the substrate edge is treated with the process medium.

It should be noted that the disclosure is not limited to the embodiment described and illustrated as examples. A large variety of modifications have been described and more are part of the knowledge of the person skilled in the art. These and further modifications as well as any replacement by technical equivalents may be added to the description and figures, without leaving the scope of the protection of the disclosure and of the present patent.

What is claimed is:

1. An apparatus for the wet-chemical processing, namely for coating of the surfaces of flat, thin and fracture-sensitive substrates, such as microelectronic components, solar cells, and the like, with a liquid process medium, wherein absorbing, compressible microporous rollers are provided on both sides of a substrate for substrate transport and for coating with said liquid process medium, the compressible microporous rollers performing a rolling, i.e., slippage-free motion on the substrate's surface, thereby transporting the substrate without transferring of forces perpendicular to the direction of transport onto the substrate's surface, the rollers conveying and guiding the substrate through the apparatus and by their rolling, i.e., slippage-free motion on the substrate's surface simultaneously transmitting the process medium absorbed by the roller onto the substrate and uniformly coating the substrate's surface, thus carrying out the wet-chemical process, the compressible microporous rollers being rotated such that the drives are coupled on at least one side in order to achieve uniform movement of the substrate so that the forces perpendicular to the direction of transport are not transferred onto the substrate's surface.

2. The apparatus according to claim 1, characterized in that a media bath is provided and that the roller is immersed in the media bath and absorbs the process medium.

3. The apparatus according to claim 1, characterized in that a spraying device is provided such that the process medium is fed to the roller by spraying onto the roller and/or by metering the process medium between the rollers.

4. The apparatus according to claim 1, characterized in that the rollers are disposed on top of one another, thereby, forming upper rollers and lower rollers, and that the positions of the rollers disposed on top of one another are adjustable.

5. The apparatus according to claim 4, characterized in that the distance and/or pressure of the upper rollers to or on the lower rollers is adjustable.

6. The apparatus according to claim 1, characterized in that the absorbed liquid of the roller can be removed by suctioning it out of the roller.

7. The apparatus according to claim 1, characterized in that a plurality of process chambers are disposed in series to form a process line in order to be able to consecutively perform etching processes, rinsing processes, drying processes and the like.

8. A method for the wet-chemical processing, namely for coating of surfaces of flat, thin and fracture-sensitive substrates, such as microelectronic components, solar cells, and the like, with a liquid process medium, wherein absorbing, compressible microporous rollers are provided on both sides of a substrate for substrate transport and for coating with said liquid process medium, the compressible microporous rollers performing a rolling i.e. slippage-free motion on the substrate's surface, thereby transporting the substrate without transferring of forces perpendicular to the direction of transport onto the substrate's surface, the rollers conveying and guiding the substrate through the apparatus and by their rolling i.e. slippage-free motion on the substrate's surface simultaneously transmitting the process medium absorbed by the roller onto the substrate and uniformly coating the substrate's surface, thus carrying out the wet chemical process, the compressible microporous rollers being rotated such that the drives are coupled on at least one side in order to achieve uniform movement of the substrate so that the forces perpendicular to the direction of transport are not transferred onto the substrate's surface.
